(19) United States
(12) Patent Application Publication
(10) Pub. No.: US 2025/0241126 A1
(43) Pub. Date: Jul. 24, 2025

(54) LIGHT EMITTING DEVICE, DISPLAY DEVICE, IMAGE CAPTURING DEVICE, AND ELECTRONIC APPARATUS

(71) Applicant: CANON KABUSHIKI KAISHA, Tokyo (JP)

(72) Inventors: SHOMA HINATA, Kanagawa (JP); HIROAKI SANO, Tokyo (JP); KOJI ISHIZUYA, Kanagawa (JP); NORIFUMI KAJIMOTO, Kanagawa (JP); TAKAYUKI ITO, Kanagawa (JP); YOJIRO MATSUDA, Kanagawa (JP)

(21) Appl. No.: 19/175,191

(22) Filed: Apr. 10, 2025

Related U.S. Application Data
(63) Continuation of application No. PCT/JP2023/038160, filed on Oct. 23, 2023.

(30) Foreign Application Priority Data
Oct. 28, 2022 (JP) 2022-173657

(51) Int. Cl. H10K 50/858; H10K 50/856

(52) U.S. Cl. CPC H10K 50/858; H10K 50/856

(57) ABSTRACT

A light emitting device includes a plurality of light emitting portions on a surface of a substrate, wherein each of the plurality of light emitting portions includes, on the surface, a first electrode, a first light emitting layer, a charge generation layer, a second light emitting layer configured to generate light of the same color as a color of light generated by the first light emitting layer, and a second electrode in this order, the plurality of light emitting portions include a light emitting portion configured to generate light of a first wavelength and a light emitting portion configured to generate light of a second wavelength different from the first wavelength, and a lens having positive power is provided on each of the plurality of light emitting portions.

### CROSS-REFERENCE TO RELATED APPLICATIONS

This application is a Continuation of International Patent Application No. PCT/JP2023/038160, filed Oct. 23, 2023, which claims the benefit of Japanese Patent Application No. 2022-173657, filed Oct. 28, 2022, both of which are hereby incorporated by reference herein in their entirety.

### BACKGROUND OF THE INVENTION

### Field of the Invention

The present invention relates to a light emitting device, a display device, an image capturing device, and an electronic apparatus.

### Background Art

An organic light emitting element called an organic electroluminescence element (organic EL element) is an electronic element including a pair of electrodes and an organic compound layer arranged between the electrodes. Excitons of a luminous organic compound in the organic compound layer are generated by injecting electrons and holes from the pair of electrodes to the organic compound layer, and when the excitons return to a ground state, light is emitted. Recent advances in organic light emitting elements have been remarkable, and a low-driving voltage, various light emission wavelengths, high-speed responsiveness, and thinning/weight reduction of a light emitting device have been implemented.

As a method of manufacturing an organic light emitting element, there is known a method (to be referred to as a coating method hereinafter) of forming an organic layer for each color using a fine mask, photolithography, or the like. In addition, there is known a tandem-type organic light emitting element having a structure in which a charge generation layer is provided between a plurality of light emitting layers to improve the power consumption of the organic light emitting element. When an electric field is applied between a lower electrode and an upper electrode, carriers are generated in the charge generation layer, and are supplied to a first light emitting portion and a second light emitting portion. Therefore, it is possible to cause each of a light emitting layer included in the first light emitting portion and a light emitting layer included in the second light emitting portion to efficiently emit light. US-2015-0188087 discloses a configuration in which a coating method is applied to a tandem-type organic light emitting element to improve the power consumption and driving lifetime of an organic display device.

In the coating method, since it is necessary to separately form light emitting layers that emit light beams of different colors, the area of a light emitting layer corresponding to one sub-pixel can be limited by accuracy in a step, the influence of damage to an organic layer by lithography, and the like. This may decrease the ratio of the area of a light emission region to a sub-pixel area, that is, the opening ratio. In addition, in the case of the tandem type, a coating step may be performed twice or more since there are two light emitting layers, and the opening ratio can thus be limited more easily. If the opening ratio becomes low, the power consumption and the driving lifetime become insufficient. Furthermore, when the opening ratio becomes low, the ratio of a non-light emission region within a pixel increases, thereby causing a problem that the so-called screen-door effect that the non-light emission regions are visually perceived as a grid pattern in a displayed image occurs to degrade display quality. The degradation in display quality is conspicuous especially in a case where, for example, the organic light emitting element is used for a display device used in close proximity to the eyes, such as a head mounted display or an electronic viewfinder.

### SUMMARY OF THE INVENTION

One aspect of the present invention provides a technique advantageous in reducing power consumption, improving a driving lifetime, and improving display quality.

One of aspects of the present invention provides a light emitting device comprising a plurality of light emitting portions on a surface of a substrate, wherein each of the plurality of light emitting portions includes, on the surface, a first electrode, a first light emitting layer, a charge generation layer, a second light emitting layer configured to generate light of the same color as a color of light generated by the first light emitting layer, and a second electrode in this order, the plurality of light emitting portions include a light emitting portion configured to generate light of a first wavelength and a light emitting portion configured to generate light of a second wavelength different from the first wavelength, and a lens having positive power is provided on each of the plurality of light emitting portions.

Further features of the present invention will become apparent from the following description of exemplary embodiments (with reference to the attached drawings).

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1 is a schematic view showing the sectional structure of a light emitting device according to the first embodiment;

FIG. 2 is a schematic view showing the sectional structure of the light emitting device according to the first embodiment;

FIG. 3 is a schematic view showing the sectional structure of the light emitting device according to the first embodiment;

FIG. 4 is a schematic view showing the sectional structure of the light emitting device according to the first embodiment;

FIG. 5 is a schematic view showing the sectional structure of the light emitting device according to the first embodiment;

FIG. 6A is a schematic view showing an example of the arrangement of a plurality of light emitting portions (sub-pixels) in the light emitting device according to the first embodiment;

FIG. 6B is a schematic view showing an example of the arrangement of the plurality of light emitting portions (sub-pixels) in the light emitting device according to the first embodiment;

FIG. 6C is a schematic view showing an example of the arrangement of the plurality of light emitting portions (sub-pixels) in the light emitting device according to the first embodiment;

FIG. 7 is a schematic view showing the sectional structure of the light emitting device according to the first embodiment;

FIG. 8 is a schematic view showing the sectional structure of a light emitting device according to the second embodiment;

FIG. 9 is a schematic view showing the sectional structure of the light emitting device according to the second embodiment;

FIG. 10 is a schematic view showing a display device according to the third embodiment;

FIG. 11A is a schematic view showing an image capturing device according to the third embodiment;

FIG. 11B is a schematic view showing an electronic apparatus according to the third embodiment;

FIG. 12A is a schematic view showing a display device according to the third embodiment;

FIG. 12B is a schematic view showing a display device according to the third embodiment;

FIG. 13A is a schematic view showing an illumination device according to the third embodiment;

FIG. 13B is a schematic view showing a moving body according to the third embodiment;

FIG. 14A is a schematic view showing a wearable device according to the third embodiment; and

FIG. 14B is a schematic view showing a wearable device according to the third embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

The first embodiment of the present disclosure will be described below. A light emitting device according to the first embodiment includes a plurality of light emitting portions on the surface of a substrate. Each of the plurality of light emitting portions can include, on the surface of the substrate, a first electrode, a first light emitting layer, a charge generation layer, a second light emitting layer configured to generate light of the same color as the color of light generated by the first light emitting layer, and a second electrode in this order. The plurality of light emitting portions can include a light emitting portion configured to generate light of a first wavelength and a light emitting portion configured to generate light of a second wavelength different from the first wavelength. A lens having positive power can be provided on each of the plurality of light emitting portions. The lens may be understood as a microlens. In this specification, a direction perpendicular to the surface (main surface) of the substrate is described as a “vertical direction” and a direction parallel to the surface of the substrate is described as a “horizontal direction”. A vertex (end) of a curved portion in the vertical direction is simply described as “the vertex of the curved portion”. Note that various members may be provided on the substrate in addition to the lenses and the light emitting elements. The same color may be a color whose difference in peak of the emission wavelength is within 30 nm or 15 nm, or a color having the same wavelength.

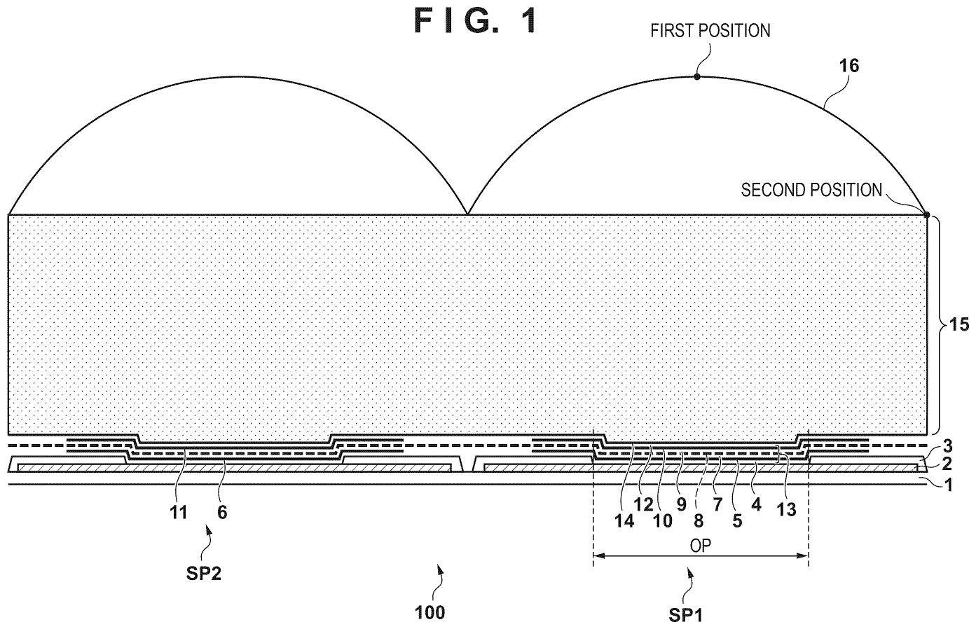

FIG. 1 is a schematic view exemplifying the sectional structure of a light emitting device 100 according to the first embodiment. The light emitting device 100 shown in FIG. 1 can include a substrate 1, a first light emitting portion SP1, and a second light emitting portion SP2. A microlens 16 can be arranged on each of the first light emitting portion SP1 and the second light emitting portion SP2. The first light emitting portion SP1 includes a first light emitting layer 5, a charge generation layer 8, and a second light emitting layer 10 on the surface of the substrate 1 in this order, and the second light emitting portion SP2 includes a third light emitting layer 6, the charge generation layer 8, and a fourth light emitting layer 11 on the surface of the substrate 1 in this order. The first light emitting layer 5 and the second light emitting layer 10 generate light of a first color, and the third light emitting layer 6 and the fourth light emitting layer 11 generate light of a second color different from the first color. The first light emitting layer 5 and the third light emitting layer 6 can be formed by, for example, the coating method using a fine mask, photolithography, or the like. Similarly, the second light emitting layer 10 and the fourth light emitting layer 11 can be formed by, for example, the coating method using a fine mask, photolithography, or the like.

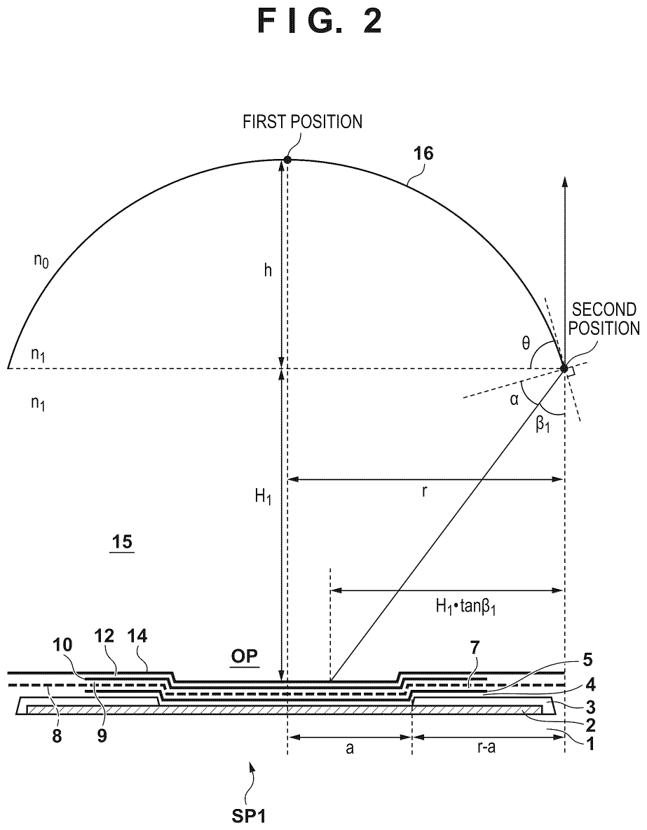

FIG. 2 is an enlarged schematic view of a portion associated with the first light emitting portion SP1 and the microlens 16 corresponding to it in FIG. 1. The configuration of the first light emitting portion SP1 will representatively be described here but another light emitting portion can have the same configuration. FIGS. 1 and 2 each schematically show a section obtained by cutting the light emitting device 100 by a plane parallel to a normal to the surface of the substrate 1 and passing through the vertex of the curved portion of the microlens 16. In this embodiment, a refractive index n1 of the microlens 16 is larger than 1, and the curved portion of the microlens 16 is formed by a part of a spherical surface, and is a curved portion that is convex in a direction away from the surface of the substrate 1 (that is, convex upward). Furthermore, the light emitting device 100 includes, between a light emitting portion (organic film 13) and the microlens 16, no layer having a refractive index smaller than the refractive index n1 of the microlens 16. As shown in FIG. 2, by refraction on the interface between the microlens 16 and air, the curved portion of the microlens 16 has the effect of causing light exiting from the light emitting portion in an oblique direction to exit in the front direction (a direction parallel to the normal to the surface of the substrate 1) in air, that is, positive power on light from the light emitting portion. From another viewpoint, the microlens 16 has the effect as a collimator that condenses, in the normal direction of the surface of the substrate 1, the light exiting from the light emitting portion in the oblique direction. The shape of the bottom surface of the microlens 16 (the shape obtained by connecting the ends of the curved portion of the microlens) when observed from the normal direction of the surface of the substrate 1 can be a circular shape with a radius r. Assuming that an opening OP of the light emitting portion SP1 has a circular shape with a radius a, if no microlens 16 is provided, the area of the light emitting portion SP1 is πa². On the other hand, if the microlens 16 is provided as in this embodiment, a light emission area (apparent light emission area) when observed from the front direction is enlarged to πr² at most by the positive power of the curved portion of the microlens 16. Since the enlargement effect increases the amount of light extracted in the front direction, the power consumption and the driving lifetime are improved. In addition, since the apparent light emission area within the pixel increases and the area of the non-light emission region decreases, degradation in display quality caused by the screen-door effect occurring when the non-light emission regions are visually perceived is suppressed. Therefore, this configuration is advantageous for application to a display device arranged in close proximity to the eyes, like a display device applied to smartglasses or an electronic viewfinder.

A preferred configuration according to this embodiment will be described below. In the example shown in FIG. 2, as described above, the curved portion of the microlens 16 is a part of a spherical surface. A position (second position) at which a tilt angle θ (an angle with respect to a plane parallel to the surface of the substrate 1) of the curved portion of the microlens 16 is maximum is the end of the curved portion of the microlens 16. Let h be a distance (microlens height) in the vertical direction (first direction) from the vertex (first position) of the curved portion to the end (second position) of the curved portion and r be a distance in the horizontal direction (second direction) from the vertex of the curved portion to the end of the curved portion. By using h and r, θ is given by sin θ=2rh/(r²+h²).

Consider a light beam that is extracted in the front direction of the light emitting device 100 in air (medium) having a refractive index no when light generated by the light emitting portion SP1 is refracted at the end (second position) of the curved portion of the microlens 16, that is, the position of the tilt angle θ. The light beam extracted in the front direction in air enters the curved portion of the microlens 16 at an incident angle α (an angle with respect to a normal to the curved portion). Based on Snell's law, n₁·sin α=n₀·sin θ holds. An angle (light beam angle) β₁ formed by the light beam and the front direction is given by θ−α.

A condition that there exists a light beam traveling from the opening OP of the light emitting portion to the end (second position) of the curved portion of the microlens 16 at the angle β₁ is given by expression (1) below. In expression (1), H₁ represents a distance from the light emitting portion to the microlens in the vertical direction of a layer. In the example shown in FIG. 2, the refractive index of the layer is n₁ that is equal to the refractive index of the microlens 16.

$$r - a < {H}_{1} \cdot tan {β}_{1} < r + a \qquad ( 1 )$$

That is, when expression (1) is satisfied, light generated by the light emitting portion is refracted at the end (second position) of the curved portion of the microlens and extracted in the front direction, and the apparent light emission area is enlarged to πr². If expression (1) is satisfied, a light beam emitted from a given point in the light emission region of the light emitting portion is refracted, in a direction parallel to the normal to the surface of the substrate 1, at a position in the curved portion of the microlens 16 where the tilt angle θ with respect to the plane parallel to the surface of the substrate 1 is largest. On the other hand, if expression (1) is not satisfied, there is no light beam from the light emitting portion, which is refracted at the end of the curved portion of the microlens and extracted in the front direction, the apparent light emission area is smaller than πr². For the above reasons, in a case where expression (1) is satisfied, the enlargement effect of the apparent light emission area becomes larger than in a case where expression (1) is not satisfied. This improves the power consumption and the driving lifetime, and also improves display quality.

In the above description, it has been considered a case where the curved portion of the microlens is a part of a spherical surface and a point at which the tilt angle θ is largest is the end of the curved portion. However, the curved portion may be an aspherical surface. In addition, the second position at which the tilt angle θ is largest may not be the end of the curved portion and the microlens 16 may have a thickness at the second position. The shape of the opening is not limited to the circular shape, and may be, for example, a square shape, a rectangular shape other than a square shape, a polygonal shape, or the like. In this case, the distance from the center of the opening to its end in a section perpendicular to the surface of the substrate may be represented by a.

In the above description, it has been considered a case where the refractive index of the medium from the light emitting portion to the microlens is equal to the refractive index n₁ of the microlens. However, a layer having a refractive index different from that of the microlens may be arranged between the light emitting portion and the microlens, or a plurality of layers having different refractive indices may be arranged. For example, a protection layer having a refractive index n₂ may be arranged between the light emitting portion and the microlens and n₁<n₂ may be satisfied. Considering refraction on the interface between the microlens and the protection layer, the condition that the relationship of r−a<H₁·tan β₁ is satisfied is the necessary condition for enlarging the apparent light emission area to πr².

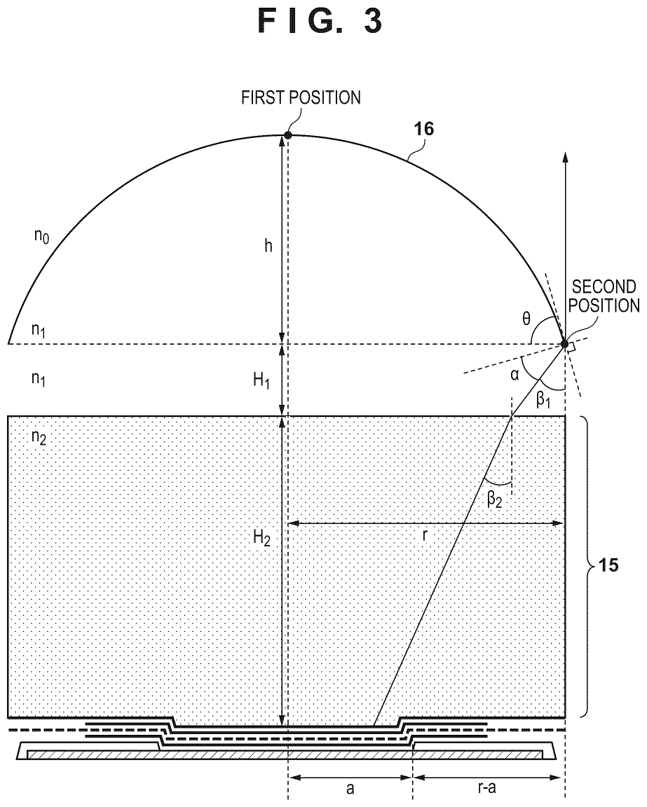

In a case where a layer having a refractive index different from that of the microlens is arranged between the light emitting portion and the microlens, a more preferable condition will be described with reference to FIG. 3. Similar to the example shown in FIG. 2, h represents the distance in the vertical direction from the first position to the second position of the microlens 16 having the refractive index n₁, r represents the distance in the horizontal direction, and the opening of the light emitting portion has a circular shape with the radius a. Furthermore, H₁ represents the thickness of the microlens 16 at the second position. In addition, a protection layer 15 having the refractive index n₂ and the thickness H₁ is arranged between the light emitting portion and the microlens 16.

Similar the above-described example, the light beam angle β₁ at which the light beam refracted at the second position and extracted in the front direction enters the second position of the microlens 16 is given by the following equations using the tilt angle θ at the second position.

$${n}_{1} \cdot sin α = {n}_{0} \cdot sin θ \\ {β}_{1} = θ - α$$

In consideration of refraction on the interface between the microlens 16 and the protection layer 15, a light beam angle β₂ in the protection layer 15 is given by the following equation.

$${n}_{2} \cdot sin {β}_{2} = {n}_{1} \cdot sin {β}_{1}$$

At this time, the condition that the light beam refracted at the second position and extracted in the front direction exits from the opening of the light emitting portion is that expression (2) below is satisfied.

$$r - a < {H}_{1} \cdot tan {β}_{1} + {H}_{2} \cdot tan {β}_{2} < r + a \qquad ( 2 )$$

That is, when expression (2) is satisfied, light generated by the light emitting portion is refracted at the second position of the microlens 16 and extracted in the front direction, and the apparent light emission area is enlarged to πr². That is, in a case where a layer having a refractive index different from that of the microlens is arranged between the light emitting portion and the microlens, when expression (2) is satisfied, the enlargement effect of the apparent light emission area becomes larger than in a case where expression (2) is not satisfied. This improves the power consumption and the driving lifetime, and also improves display quality.

The medium between the light emitting portion and the microlens is not limited to the protection layer, and for example, one or a plurality of other functional layers such as a color filter layer and/or a planarizing layer may be arranged. If a plurality of layers having different refractive indices are arranged, the refractive index of the thickest layer may be n₂ or the average value of the refractive indices weighted in accordance with the thicknesses of the layers may be used. Furthermore, by calculating the light beam angle in consideration of refraction on the interface between the layers, the condition that the light beam refracted at the second position and extracted in the front direction exits from the light emitting portion may be considered. More specifically, in a case where n layers including the microlens are arranged, if the microlens is set as the first layer and the refractive index of the ith layer from the microlens in the stacking order is nᵢ, the light beam angle in the ith layer is given by the following equation, similar to the above-described example.

$${n}_{i} \cdot sin {β}_{i} = {n}_{1} \cdot sin {β}_{1}$$

Thus, when Hᵢ represents the thickness of the ith layer, the condition that the light beam refracted at the second position and extracted in the front direction exits from the opening of the light emitting portion is that a value obtained by adding Hᵢ·tan βᵢ up to the nth layer is larger than r−a and smaller than r+a. That is, expression (3) below is preferably satisfied.

$$r - a < {H}_{1} \cdot tan {β}_{1} + {H}_{2} \cdot tan {β}_{2} + … + {H}_{n} \cdot tan {β}_{n} < r + a \qquad ( 3 )$$

As described above, when one of expressions (1) to (3) is satisfied, the efficiency of extracting light in the front direction is improved. On the other hand, by decreasing the distance in the vertical direction between the microlens and the light emitting portion, the amount of light entering the microlens increases. That is, when one of expressions (1) to (3) is satisfied and then the distance in the vertical direction between the microlens and the light emitting portion is decreased, the amount of light extracted on the wide angle side increases, thereby improving a viewing angle characteristic. In terms of improving the viewing angle characteristic, it is possible to decrease the distance from the light emitting portion in the vertical direction by providing no color filter layer.

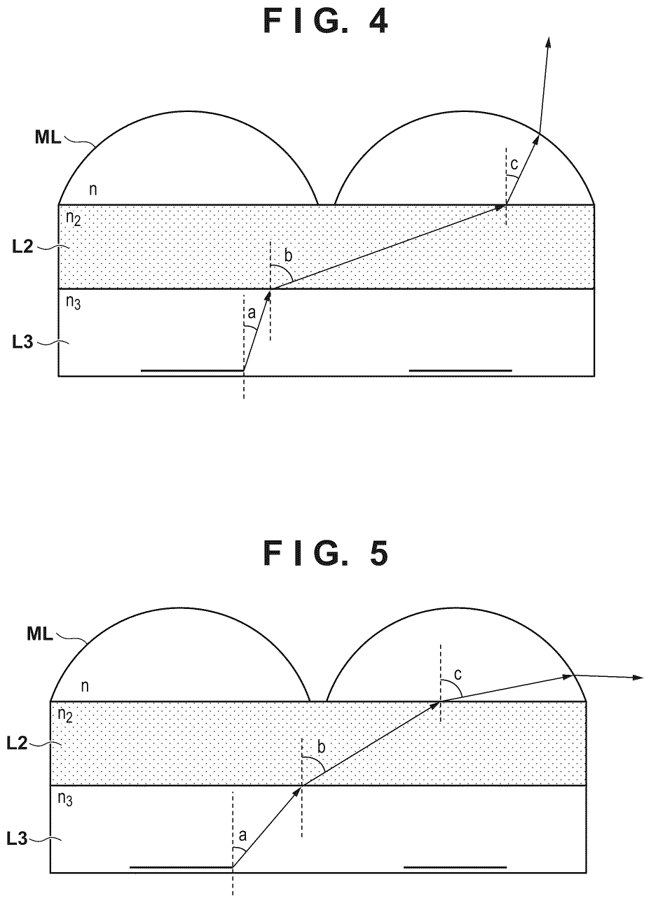

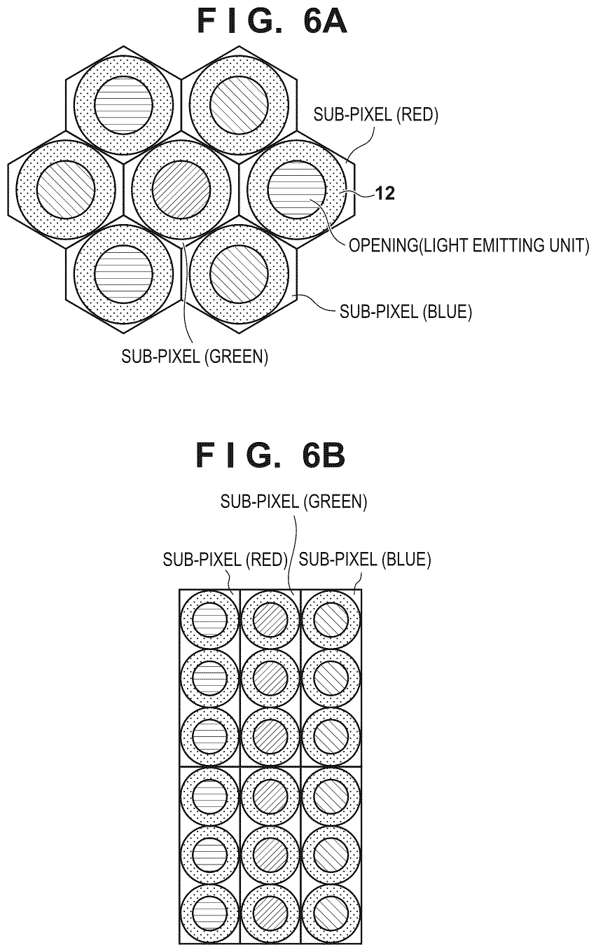

The preferable relationship between the refractive indices of layers provided between the microlens and the light emitting portion will be described. FIGS. 4 and 5 are sectional views each schematically showing an example of a configuration in which layers having different refractive indices are provided between the light emitting portion and the microlens 16. FIGS. 4 and 5 each show two adjacent light emitting portions. Two layers L3 and L2 are arranged between the light emitting portion and the microlens 16 having the refractive index n₁, and have refractive indices n₂ and n₃, respectively. The layer L3 may be, for example, a protection layer, and the layer L2 may be, for example, a color filter or a planarizing layer. In the example shown in FIG. 4, the magnitude relationship among the refractive indices is n₂<n₁<n₃. Considering the refraction of the light beam exiting from the light emitting portion in the oblique direction, the magnitude relationship among angles a, b, and c is a<c<b in accordance with the magnitude relationship among the refractive indices. Especially, when c<b is satisfied, the light beam is bent in the front direction on the interface between the layer L3 and the microlens 16, and thus the light from the light emitting portion may exit from the microlens of the adjacent light emitting element in a direction close to the front direction, as shown in FIG. 4. That is, since the radiation angle from the light emitting portion is large and light with low color purity is readily, visually perceived, color purity may lower. On the other hand, in the example of FIG. 5 in which the magnitude relationship among the refractive indices is n₁<n₂<n₃, since a<b<c is satisfied, the light exiting from the light emitting portion in the oblique direction is refracted on the wide angle side on the interface between the layer L3 and the microlens 16, and thus hardly exits in the front direction, thereby making it possible to suppress lowering of color purity. For the above reasons, by arranging no layer having a refractive index smaller than that of the microlens between the microlens and the light emitting portion, it is possible to suppress lowering of color purity.

The preferable range of the width a of the opening of the light emitting portion will be described next. As described above, the effect of improving the light extraction efficiency of the microlens 16 is provided by providing the microlens to enlarge the apparent light emission area. Therefore, this effect can be considered to be nearly proportional to the ratio between the apparent light emission area and the area of the opening of the light emitting portion. That is, as the ratio r/a between the distance r in the horizontal direction from the first position to the second position of the microlens and the width a of the opening is higher, the effect of improving the light extraction efficiency is larger and the effect of reducing the power consumption is larger. To produce the effect of reducing the power consumption, r/a>1 is preferably satisfied, r/a>1.5 is more preferably satisfied, and r/a>2 is still more preferably satisfied.

On the other hand, light exiting from a point outside the opening is refracted by the lens and extracted on the wide angle side. That is, as the width a of the opening is larger, light extracted on the wide angle side increases. Therefore, as the width a of the opening is larger, the viewing angle characteristic is improved. In terms of improving the viewing angle characteristic, r/a<5 is preferably satisfied and r/a<4 is more preferably satisfied.

The preferable value range of the distance h in the vertical direction and the distance r in the horizontal direction from the first position to the second position of the microlens will be described next. In a case where h=r, that is, h/r=1, when the curved portion of the microlens is a spherical surface, the tilt angle θ at the second position is 90°. A light beam that passes through the second position with θ=90° to exit in the front direction is light entering at a critical angle. In a case where one of expressions (1) to (3) is satisfied with respect to the light beam, light that exits outside the opening and reaches the second position is totally reflected at the second position, and is not extracted from the microlens. Thus, h/r<1 is preferably satisfied since the extraction efficiency is improved.

When the lens aberration is larger as h/r is higher, a light beam that is not effectively used may be generated, thereby degrading the light extraction efficiency. Therefore, h/r is preferably low, and h/r<0.95 is preferably satisfied and h/r<0.8 is more preferably satisfied.

The detailed configuration of the light emitting device 100 will exemplarily be described below with reference to FIG. 1. The light emitting device 100 can include the substrate 1, a plurality of first electrodes 2, an insulating layer (bank) 3, the organic film 13, a second electrode 14, the protection layer 15, and the microlenses 16. The plurality of first electrodes 2 are provided on the surface of the substrate 1. The organic film 13 can include a first functional layer 4, the first light emitting layer 5, the third light emitting layer 6, a second functional layer 7, the charge generation layer 8, a third functional layer 9, the second light emitting layer 10, the fourth light emitting layer 11, and a fourth functional layer 12. The first light emitting layer 5 and third light emitting layer 6 are arranged between the first functional layer 4 and the second functional layer 7, and the second light emitting layer 10 and the fourth light emitting layer 11 are arranged between the third functional layer 9 and the fourth functional layer 12. The second electrode 14 is arranged on the organic layer 13. The organic layer 13 forms a light emitting portion and emits light by a potential difference applied between the first electrode 2 and the second electrode 14. The insulating layer 3 forms a bank and is arranged to insulate the plurality of first electrodes 2 from each other. The insulating layer 3 has the opening OP to expose the first electrode 2 to the organic layer 13. The insulating layer 3 may include a plurality of insulating portions respectively provided for the plurality of first electrodes 2, or may be formed as one insulating layer having a plurality of openings OP respectively corresponding to the plurality of first electrodes 2. The first electrode 2 and the organic layer 13 contact each other in the opening OP, and a portion of the organic layer 13 corresponding to the opening OP of the insulating layer 3 functions as a light emission region. The light emitting device 100 can be understood as a device including the plurality of light emitting portions SP1, SP2, . . . respectively corresponding to the plurality of first electrodes 2. The plurality of light emitting portions may be understood as a plurality of pixels or a plurality of sub-pixels. In the example shown in FIG. 1, the first light emitting portion SP1 includes, on the substrate 1, the first electrode 2, the first light emitting layer 5 configured to generate light of the first color, the charge generation layer 8, the second light emitting layer 10 configured to generate light of the first color, and the second electrode 14 in this order. The second light emitting portion SP2 includes, on the substrate 1, the first electrode 2, the third light emitting layer 6 configured to generate light of the second color different from the first color, the charge generation layer 8, the fourth light emitting layer 11 configured to generate light of the second color, and the second electrode 14 in this order. The charge generation layer 8 may be provided commonly for the plurality of light emitting portions SP1, SP2, . . . or individually for each of the plurality of light emitting portions SP1, SP2, . . . . The first electrode 2 can be provided individually for each of the plurality of light emitting portions SP1, SP2, . . . and the second electrode 14 can be provided commonly for the plurality of light emitting portions SP1, SP2, . . . .

The protection layer 15 can be arranged on the second electrode 14. The plurality of microlenses 16 can be arranged on the protection layer 15 to correspond to the plurality of light emitting portions, respectively. The material of the substrate 1 is not particularly limited as long as the material can support the first electrode 2, the organic layer 13, and the second electrode 14. For example, glass, plastic, silicon, or the like can be used as the material of the substrate 1. A switching element such as a transistor, a wiring, an interlayer insulating film, and the like may be provided on the substrate 1.

The first electrode 2 may be transparent or opaque. If the first electrode 2 is opaque, the material of the first electrode 2 is preferably a metal material whose reflectance at the light emission wavelength is 70% or more. For example, as the material of the first electrode 2, a metal such as Al or Ag or an alloy obtained by adding Si, Cu, Ni, Nd, or the like to Al or Ag can be used. Alternatively, as the material of the first electrode 2, ITO, IZO, AZO, IGZO, or the like can be used. Note that the light emission wavelength means the spectrum range of light emitted from the organic layer 13. As long as the reflectance of the first electrode 2 is higher than a predetermined (desired) reflectance, the first electrode 2 may be a stacked electrode with a barrier electrode made of a metal such as Ti, W, Mo, or Au, or an alloy thereof, or a stacked electrode with a transparent oxide film electrode made of ITO, IZO, or the like.

On the other hand, if the first electrode 2 is transparent, a reflective layer may be provided under the first electrode 2 (on the side of the substrate 1). As the material of the transparent first electrode 2, for example, ITO, IZO, AZO, IGZO, or the like can be used. To optimize an optical distance to be described later, a configuration in which an insulating film is provided between the reflective layer and a transparent conductive film may be adopted as the configuration of the first electrode 2. A configuration in which the film thickness of the insulating film or the transparent conductive film is changed for each light emitting portion in accordance with the color of light emitted by the light emitting portion (light emitting element) may be adopted.

The second electrode 14 is transmissive. The material of the second electrode 14 may be a semi-transmissive material having a characteristic of transmitting part of light that has reached the surface of the second electrode 14 and reflecting the remaining part of the light (that is, a transflective property). As the material of the second electrode 14, for example, a transparent material such as a transparent conductive oxide can be used. As the material of the second electrode 14, a semi-transmissive material of a single metal (aluminum, silver, gold, or the like), an alkali metal (lithium, cesium, or the like), an alkali earth metal (magnesium, calcium, barium, or the like), or an alloy material containing these metal materials can be used. If a semi-transmissive material is used as the material of the second electrode 14, an alloy containing magnesium or silver as a main component is preferably used as a semi-transmissive material. The second electrode 14 may have a stacked structure including a plurality of layers made of the above-described materials as long as it has a preferable transmittance. In FIG. 1, one second electrode 14 common to the plurality of light emitting portions is provided, but a plurality of second electrodes 14 respectively corresponding to the plurality of light emitting portions may be provided.

One of the first electrode 2 and the second electrode 14 functions as an anode, and the other functions as a cathode. For example, the first electrode 2 functions as an anode and the second electrode 14 functions as a cathode. The first electrode 2 may function as a cathode and the second electrode 14 may function as an anode.

Each of the first to fourth functional layers can be formed by a known technique such as a deposition method or a spin coating method, and may be formed from a plurality of layers. Each functional layer includes at least one of a hole injection layer, a hole transport layer, an electron blocking layer, a hole blocking layer, an electron transport layer, and an electron injection layer. The first to fourth functional layers may be formed to cover the plurality of first electrodes or may be formed separately in one-to-one correspondence with the first electrodes using a fine mask, photolithography, or the like. In addition, to optimize an optical distance to be described later, the film thicknesses of the functional layers stacked on each first electrode may be different for each first electrode.

Each of the first to fourth light emitting layers emits light when holes injected from the anode and electrons injected from the cathode are recombined in the organic compound layer. Each light emitting layer may include a single layer or a plurality of layers. In this embodiment, the first light emitting layer 5 and the third light emitting layer 6 are patterned and formed for each light emitting portion using a fine mask, photolithography, or the like. In the example shown in FIG. 1, the first light emitting layer 5 and the third light emitting layer 6 are formed separately so they do not overlap each other in a planar view from the vertical direction but may be formed to overlap each other outside the opening of the first electrode 2. The first light emitting layer 5 and the third light emitting layer 6 contain different light emitting materials and emit light beams of different colors. For example, the first light emitting layer 5 may be a red light emitting layer containing a red light emitting material, and the third light emitting layer 6 may be a green light emitting layer containing a green light emitting material. In the example of this embodiment, the first light emitting layer 5 and the second light emitting layer 10 are light emitting layers of the same color, and the third light emitting layer 6 and the fourth light emitting layer 11 are light emitting layers of the same color. By adopting the tandem configuration in which light emitting layers that emit light beams of the same color are stacked, it is possible to improve color purity and the driving lifetime. However, the present invention is not limited to this, and light emitting layers of different colors may be combined.

The charge generation layer 8 is a layer that generates holes and electrons when a voltage is applied between the first electrode 2 and the second electrode 14. The charge generation layer 8 contains a compound that readily accepts electrons from another organic compound. The charge generation layer 8 may be a combination of, for example, an alkali metal and a compound with a lowest unoccupied molecular orbital energy of −5.0 eV or less, and can function as a charge generation layer. The lowest unoccupied molecular orbital energy of the charge generation layer may be energy lower than the highest occupied molecular orbital energy of the first or second light emitting layer. The lowest unoccupied molecular orbital energy of the charge generation layer may be energy lower than the highest occupied molecular orbital energy of the hole transport layer. The hole transport layer can be an organic layer arranged between the charge generation layer and the second light emitting layer.

The alkali metal can be, for example, Li, and Li may be contained as a metal, a part of a compound, or a part of an organometallic complex. The compound with a lowest unoccupied molecular orbital energy of −5.0 eV or less can be, for example, a hexaazatriphenylene compound, a radialene compound, or hexafluoroquinodimethane. However, the compound is not limited to these. If the lowest unoccupied molecular orbital energy is so low that electrons are extracted from the highest occupied molecular orbit of the alkali metal, charges can be generated. Since positive or negative charges are thus generated in the charge generation layer 8, the positive or negative charges can be supplied to the layers on the upper and lower sides of the charge generation layer 8. That is, when an electric field is applied between the first electrode 2 and the second electrode 14, carriers are generated in the charge generation layer 8. The carriers are supplied to the first light emitting layer 5 and the second light emitting layer 10 and the third light emitting layer 6 and the fourth light emitting layer 11, which can efficiently be caused to emit light. The description is given here assuming that the closer the highest occupied molecular orbital energy (HOMO) and lowest unoccupied molecular orbital energy (LUMO) are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*, or the like. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by measurement in which the compound to be measured is dissolved in a solvent such as toluene, and it is irradiated with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using CV (cyclic voltammetry) measurement. The CV measurement can be performed, for example, in a DMF solution of 0.1 M tetrabutylammonium perchlorate using a reference electrode of Ag/Ag+, a counter electrode of Pt, and a working electrode of glassy carbon. The LUMO can be estimated by adding −4.8 eV to the difference between the reduction potential of the obtained compound and that of ferrocene.

If charges leak to an adjacent pixel via the charge generation layer 8, the adjacent pixel unintentionally emits light, thereby degrading display quality. To suppress this, the charge generation layers 8 may be formed separately in one-to-one correspondence with the first electrodes using a fine mask, photolithography, or the like. For the same purpose, a concave portion or a convex portion may be formed between the light emitting portions (pixels) on the substrate, and then the film thickness of the charge generation layer 8 deposited between the light emitting portions (pixels) may be made thin.

The light emitting device 100 according to this embodiment may be formed as a light emitting device including a first reflective surface, a second reflective surface, and the insulating film 3 arranged between the first reflective surface and the second reflective surface. The first reflective surface may be the first electrode 2, a reflective layer arranged between the substrate 1 and the first electrode 2, or a reflective layer arranged between the first electrode 2 and the insulating layer 3. The second reflective layer may be the second electrode 14, or a semi-transmissive reflective layer arranged between the second electrode 14 and the microlens.

To optimize the optical distance between the first reflective surface and the light emitting portion (light emission position) of the organic film 13 including the light emitting layer with respect to a desired angle θeml in the organic film 13, equation (4) below is satisfied. In equation (4), Lr represents an optical path length (optical distance) from the first reflective surface to the light emission position of the organic layer 13, Φr represents a phase shift when light of a wavelength λ is reflected by the first reflective surface, and m represents an integer of 0 or more. The position of the first reflective surface, and the film thickness of the organic layer 13, and the like are optimized so as to satisfy equation (4).

$$Lr = ( 2 \times m - ( Φ r / π ) ) \times ( λ / 4 ) \times 1 / cos ( θ eml ) \qquad ( 4 )$$

Furthermore, if Φₛ represents a phase shift when light of the wavelength A is reflected by the second reflective surface, an optical distance Ls from the light emission position to the second reflective surface satisfies equation (5) below.

$$Ls = ( 2 \times {m}^{′} - ( Φ r / π ) ) \times ( λ / 4 ) \times 1 / cos ( θ eml ) = - ( Φ s / π ) \times ( λ / 4 ) \qquad ( 5 )$$

Therefore, an optical path length L between the first reflective surface and the second reflective surface satisfies equation (6) below. In equation (6), Φ represents a sum of the phase shifts Φᵣ and Φₛ.

$$L = Lr + Ls = ( 2 \times m - Φ / π ) \times ( λ / 4 ) \times 1 / cos ( θ eml ) \qquad ( 6 )$$

In this example, in equations (4) to (6) above, an allowable range is about λ/8 or about 20 nm. Therefore, expression (7) below is preferably satisfied.

$$( 2 \times m - Φ / π ) \times ( λ / 4 ) \times 1 / cos ( θ eml ) - λ / 8 < L < ( 2 \times m - Φ / π ) \times ( λ / 4 ) \times 1 / cos ( θ eml ) + λ / 8 \qquad ( 7 )$$

Note that since it may be difficult to specify the light emission position in the organic film 13, the interface on the first reflective surface side or the second reflective surface side of the first light emitting layer 5 is used instead of the light emission position in the above example. In consideration of the above-described allowable range, even if the interface is used instead, an effect of intensifying light in the front direction can be obtained. If no microlens is provided, it is possible to improve the amount of light in the front direction by optimizing the optical distance of the organic film 13, that is, the film thickness so as to satisfy equations (4) to (6) by setting the front direction, that is, θeml=0. On the other hand, if the microlens is provided, the light refracted at the second position of the microlens and extracted in the front direction is light having the light beam angle β₁ in the microlens, as described above. In consideration of the fact that the tilt angle of the curved portion of the microlens is largest at the second position and is small at the remaining points, the light refracted by the microlens and emitted in the front direction is light obtained by adding light beams having light beam angles of 0 (inclusive) to β₁ (inclusive) in the microlens. Therefore, when the refractive index of the organic film 13 is nₑₘₗ, it is considered to be able to improve the amount of light extracted in the front direction by optimizing the film thickness with respect to the angle θeml that satisfies

$$0 < θ eml < {sin}^{- 1} ( {n}_{1} \cdot sin {β}_{1} / {n}_{eml} ) ,$$

as compared to a case where the film thickness is optimized with respect to θeml=0.

That is, if the microlens is provided, in order to improve the amount of light extracted in the front direction, it is preferable to set the optical distance of the organic film 13 so that L satisfies

$$L = ( 2 \times m - Φ / π ) \times ( λ / 4 ) \times 1 / cos ( θ eml )$$

with respect to the angle θeml that satisfies 0<sin θeml<n₁·sin β₁/nₑₘₗ. Alternatively, expression (8) below is preferably satisfied.

$$( 2 m π - Φ ) \times ( λ / 4 π ) < L < ( 2 \times m - Φ / π ) \times ( λ / 4 ) \times 1 / cos ( θ eml ) + λ / 8 \qquad ( 8 )$$

At this time, θeml is arbitrarily set so as to optimize color purity and the viewing angle characteristic within a range that satisfies 0<sin θeml<n₁·sin β₁/nₑₘₗ.

As another aspect, it can be considered that it is preferable to shift, to the long wavelength side, a resonant peak wavelength λₒₙ of an interference spectrum that intensifies light emitted in the front direction and set it with respect to a peak wavelength λ_{PL} of the PL spectrum of the light emitting material contained in the light emitting layer. When the peak wavelength APL of the PL spectrum of the light emitting material is made to substantially match the resonant peak wavelength λₒₙ in the front direction, the emission spectrum intensity in the front direction is highest, and when the value of |λₒₙ−λ_{PL}| becomes larger, the emission spectrum intensity in the front direction becomes lower. As is apparent from equations (4) to (6), a resonant peak wavelength λ_{off} in an oblique direction in which θeml>0 is shorter than the resonant peak wavelength λₒₙ in the front direction in which θeml=0. Therefore, it is preferable to set the optical distance so as to satisfy a relationship of |λ_{off}−λ_{PL}|<|λₒₙ−λ_{PL}| by setting λₒₙ>λ_{PL} since the amount of light extracted in the front direction can be improved.

As still another aspect, in consideration of a peak wavelength λ_{EL} of EL light emission via the microlens, it is possible to improve the amount of light extracted in the front direction by satisfying a relationship of |λ_{EL}−λ_{PL}|<|λₒₙ−λ_{PL}|. As described above, light emitted via the microlens is light obtained by adding light beams having light beam angles of 0 (inclusive) to β₁ (inclusive) in the microlens. Therefore, λ_{EL} is shorter than λₒₙ. It is thus possible to improve the amount of light extracted in the front direction by satisfying the relationship of

$$\vert {λ}_{EL} - {λ}_{PL} \vert < \vert {λ}_{on} - {λ}_{PL} \vert .$$

The protection layer 15 is an insulating layer, is transmissive, and preferably contains an inorganic material having a low permeability for oxygen and water from the outside. For example, the protection layer 15 may be formed using an inorganic material such as silicon nitride (SiN), silicon oxynitride (SiON), silicon oxide (SiOx), aluminum oxide (Al₂O₃), or titanium oxide (TiO₂). In particular, in terms of the protection performance, an inorganic material such as SiN, SiON, or Al₂O₃ is preferable. A chemical vapor deposition method (CVD method), an atomic layer deposition method (ALD method), a sputtering method, or the like can preferably be used to form the protection layer 15.

The protection layer 15 can have a single-layer structure or a stacked structure using the above-described materials and forming methods in combination as long as the protection layer 15 has sufficient water block performance. For example, the protection layer 15 may have a stacked structure of a layer of silicon nitride and another layer having a high density formed using the atomic layer deposition method. Furthermore, the protection layer 15 may include an organic layer as long as it has water block performance. For example, the organic layer is made of polyacrylate, polyamide, polyester, epoxy, or the like. In addition, in FIG. 1, the one protection layer 15 common to the plurality of light emitting portions is provided but a plurality of protection layers 15 respectively corresponding to the plurality of light emitting portions may be provided.

The microlens 16 can be formed by an exposure process and a developing process. More specifically, a film (photoresist film) is formed using the material of the microlens 16, and the photoresist film is exposed and developed using a mask including a continuous change in gradation. As the mask, a gray mask can be used. An area gradation mask that allows light irradiation with a continuous change in gradation on the imaging plane by changing the density distribution of dots of a light shielding film with a resolution equal to or smaller than the resolution of an exposure device can also be used. The lens shape can be adjusted by etching back the microlens 16 formed by the exposure process and the developing process. As described above, the microlens 16 need only have the curved portion where positive power acts on light from the light emitting portion, and the curved portion may or may not be a part of a spherical surface. More specifically, as in this embodiment, the curved portion of the microlens projects on the light extraction side, and is a curved surface that is convex upward in a case where light is extracted in a layer, such as air, having a refractive index lower than that of the microlens. Furthermore, by forming a curved surface that satisfies the relationship of one of expressions (1) to (3), the effect of improving the power consumption and driving lifetime and the effect of suppressing degradation in display quality become large.

In the example shown in FIG. 1, a layer contacting the microlens 16 on the light extraction side is air. However, the refractive index no of the layer need only be lower than the refractive index n₁ of the microlens, and for example, a transparent resin may be arranged on the microlens.

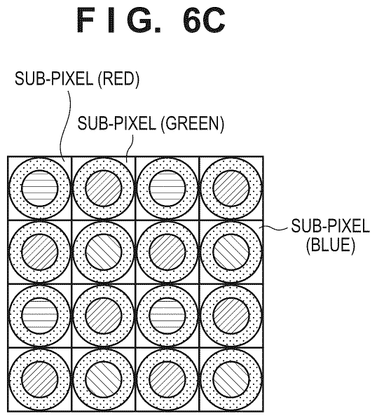

The light emitting element is formed by a combination of the light emitting portion, the curved portion of the microlens 16, and the like. If a plurality of light emitting elements are provided, the planar arrangement (the arrangement when viewed from the vertical direction) of the plurality of light emitting elements may be any of a stripe arrangement, a square arrangement, a delta arrangement, a pentile arrangement, and a Bayer arrangement. A configuration in which the plurality of curved portions of the microlenses 16 emit light beams of different colors may be adopted. This allows full-color display. FIGS. 6A to 6C are plan views when viewing the light emitting device from the side of the microlens 16, and each show an example of the planar arrangement of the plurality of light emitting elements. FIG. 6A shows an example of the delta arrangement. FIG. 6B shows an example of the stripe arrangement. FIG. 6C shows an example of the Bayer arrangement. In this example, consider a case where the light emitting device is used as a display panel, and one pixel (main pixel) includes a plurality of sub-pixels having different corresponding color components (for example, a sub-pixel that performs red display, a sub-pixel that performs green display, and a sub-pixel that perform blue display). In this case, as shown in FIG. 6B, the plurality of light emitting elements may be provided in one sub-pixel. The size and shape of the curved portion of the microlens 16 may appropriately be set in accordance with the planar arrangement of the plurality of light emitting elements. If the delta arrangement is adopted, an area occupied by the curved portion of the microlens 16 with respect to the sub-pixel can be set large, thereby improving light extraction efficiency.

In the examples shown in FIGS. 6A to 6C, the planar shape of the light emitting portion (the shape when viewed from the vertical direction) is a circular shape but the planar shape of the light emitting portion is not particularly limited and may be, for example, a polygonal shape such as a rectangular or hexagonal shape. However, if the planar shape of the light emitting portion is a circular shape, the relationship of the tilt angle in a direction from the end of the light emitting portion to the end of the microlens 16 (curved portion) is the same in all sections obtained by a plane in the vertical direction that passes through the vertex of the curved portion, and thus the light emitting device is readily designed.

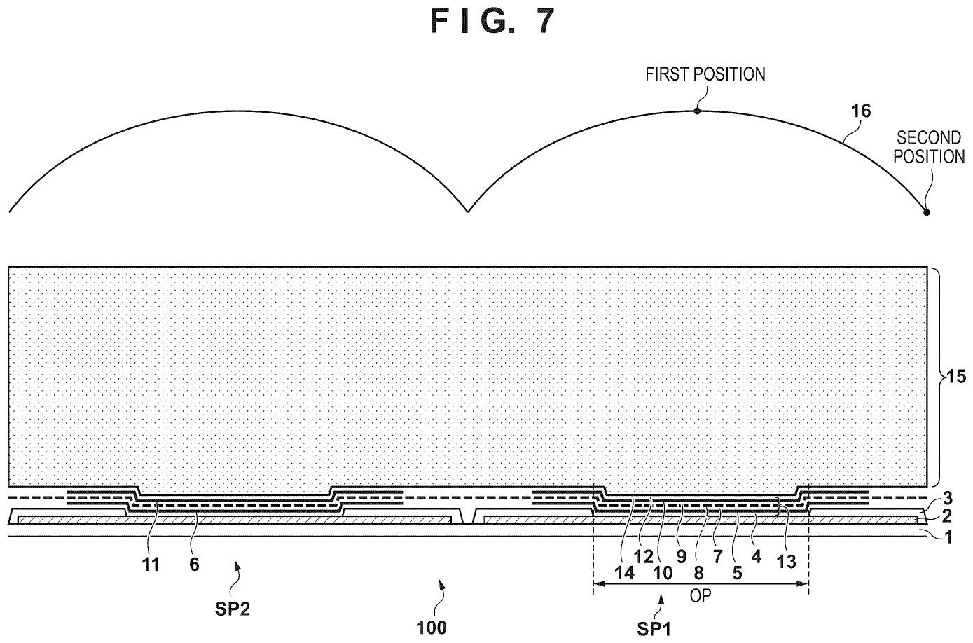

As shown in FIG. 7, the microlens 16 may be formed so that the end of the curved portion of the microlens 16 has a thickness (parts of the microlenses 16 overlap each other between the adjacent light emitting portions). In this case as well, as long as the curved portion having the effect of condensing the light from the light emitting portion is provided, it is possible to obtain the effect of improving the power consumption and driving lifetime and the effect of suppressing degradation in display quality. If the relationship of one of expressions (1) to (3) is satisfied, the effect of improving the power consumption and driving lifetime and the effect of suppressing degradation in display quality become large.

In this embodiment, the microlenses 16 are directly provided on the protection layer 15. However, a color filter or a light absorption layer may be provided for the purpose of improving color purity and the viewing angle characteristic, or a planarizing layer may be provided between the protection layer 15 and the microlenses 16 for the purpose of planarizing the unevenness of the protection layer 15. A color filter or a light absorption layer may be provided between the protection layer 15 and the microlenses 16 or may be provided on the microlenses 16. A color filter and the protection layer 15 may be integrated, the microlenses 16 and a color filter may be integrated, or a color filter may be formed on another substrate and the substrates may be bonded so as to oppose each other. As in the example of this embodiment, the protection layer and the microlens are formed integrally, thereby forming the curved portion of the microlens 16 while accurately aligning it with the light emitting portion. In addition, the distance in the vertical direction between the microlens and the light emitting portion can be made small, thereby improving the viewing angle characteristic, as described above.

A practical example of a method of manufacturing the light emitting device 100 will be described below. In this practical example, the light emitting device 100 includes three kinds of light emitting elements (light emitting portions) including a red light emitting element with a red light emitting layer, a green light emitting element with a green light emitting layer, and a blue light emitting element with a blue light emitting layer.

First, aluminum was formed on the substrate 1 and patterned, thereby forming the plurality of first electrodes 2. Next, a plurality of insulating layers were formed to cover the plurality of first electrodes 2, respectively. The material of the insulating layers was silicon oxide and the film thickness of each insulating layer was 65 nm. The opening OP was formed to expose the corresponding first electrode 2 (the covered first electrode 2) in each insulating layer, thereby obtaining the plurality of insulating layers 3. The shape of the opening OP was a circular shape having a radius of 0.9 μm. As described above, the opening OP of the insulating layer 3 finally exposed the corresponding first electrode 2 to the organic layer 13 corresponding to the first electrode 2. When viewed from the vertical direction, the size and shape of the opening OP matched the size and shape of the light emitting portion.

Next, the organic film 13 (organic compound layer) was formed on the first electrodes 2 (and the insulating layers 3). More specifically, first, a hole injection layer, a hole transport layer, and an electron blocking layer were sequentially formed. At this time, the hole injection layer and the hole transport layer were deposited to cover the first electrodes 2 corresponding to all the light emitting elements, and the electron blocking layer was deposited three times using a fine mask so as to be separately formed for each of the first electrodes 2 corresponding to the light emitting elements corresponding to the respective light emission colors. For the purpose of optimizing the optical distance, the film thickness of the electron blocking layer was adjusted for each light emission color. Next, a first red light emitting layer, a first green light emitting layer, and a first blue light emitting layer were separately formed by performing deposition using the fine mask three times. Next, a hole blocking layer and an electron transport layer were sequentially formed. The hole blocking layer was formed by adjusting the film thickness of the hole blocking layer for each light emission color, similar to the electron blocking layer. Next, the charge generation layer 8 was formed by codepositing an organic material and lithium. Subsequently, similarly, a hole injection layer, a hole transport layer, an electron blocking layer, a second red light emitting layer, a second green light emitting layer, a second blue light emitting layer, a hole blocking layer, and an electron transport layer were sequentially formed. The second red light emitting layer, the second green light emitting layer, and the second blue light emitting layer were separately formed by performing deposition using the fine mask three times. Subsequently, an electron injection layer was formed by lithium fluoride.

The total thickness of the organic layer 13 was 310 nm for the red light emitting element, 265 nm for the green light emitting element, and 212 nm for the blue light emitting element. These were set to intensify light roughly in a direction of θeml=15° in each light emitting element.

Next, an Mg/Ag alloy was formed to a thickness of 10 nm as the second electrode 14 on the organic layer 13. The ratio of Mg and Ag was 1:1. After that, as the protective layer 15, an SiN film with a refractive index of 1.97 was formed to a thickness of 2.1 μm on the second electrode 14 by the CVD method.

Next, the microlenses 16 with a refractive index of 1.53 were formed on the protection layer 15 using the exposure process and the developing process. The curved portion of the microlens 16 was a part of a spherical surface, and the distance h in the vertical direction from the vertex (first position) of the curved portion to the end (second position) of the curved portion was 1.4 μm and the distance r in the horizontal direction was 1.9 μm. A portion above the microlens was air with a refractive index of 1.

Since the thus manufactured light emitting device included the microlens having the curved portion where positive power acted on light from the light emitting portion, the power consumption was reduced, the driving lifetime was improved, and degradation in display quality caused by the screen-door effect was suppressed.

The tilt angle θ at the second position was calculated by sin θ=2rh/(r²+h²), thereby obtaining θ=72.8°. The incident angle α on the lens surface and the light beam angle β in the lens were calculated by n₁·sin α=n₀·sin θ and β₁=θ−α, thereby obtaining α=38.6° and β₁=34.1°, respectively. The light beam angle β₂ in the protection layer 15 was calculated by n₂·sin β₂=n₁·sin β₁, thereby obtaining β₂=25.8°. Since the distance H in the vertical direction from the light emitting portion to the end portion of the microlens 16 was 2.1 μm, H·tan β₁=1.42 μm, r−a=1 μm, and r+a=2.8 μm were obtained, and r−a<H·tan β₁<r+a was thus obtained, thereby satisfying the relationship of expression (1). Furthermore, when H₁=0 μm and H₂=2.1 μm were set, H₁·tan β₁+H₂·tan β₂=1.02 was obtained and r−a<H₁·tan β₁+H₂·tan β₂<r+a was thus obtained, thereby satisfying the relationship of expression (2). Furthermore, the radius a of the opening was 0.9 μm and r was 1.9 μm, thereby obtaining r/a=2.11. When the relationships of expressions (1) and (2) were satisfied, the apparent opening was enlarged to a circular shape having the radius r=1.9 μm. Thus, the effect of reducing the power consumption and improving the driving lifetime was large and the effect of suppressing degradation in display quality caused by the screen-door effect was large.

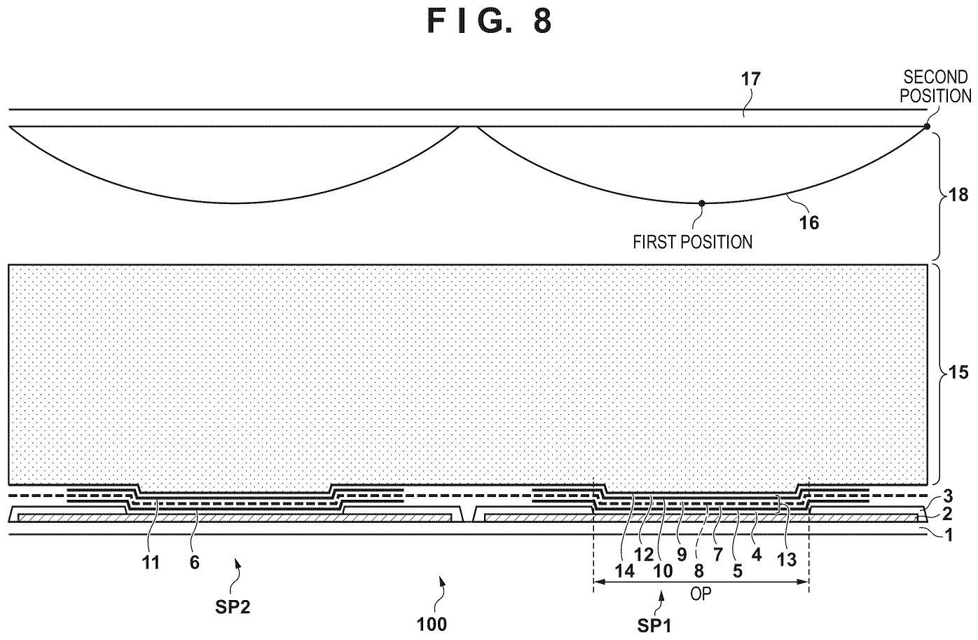

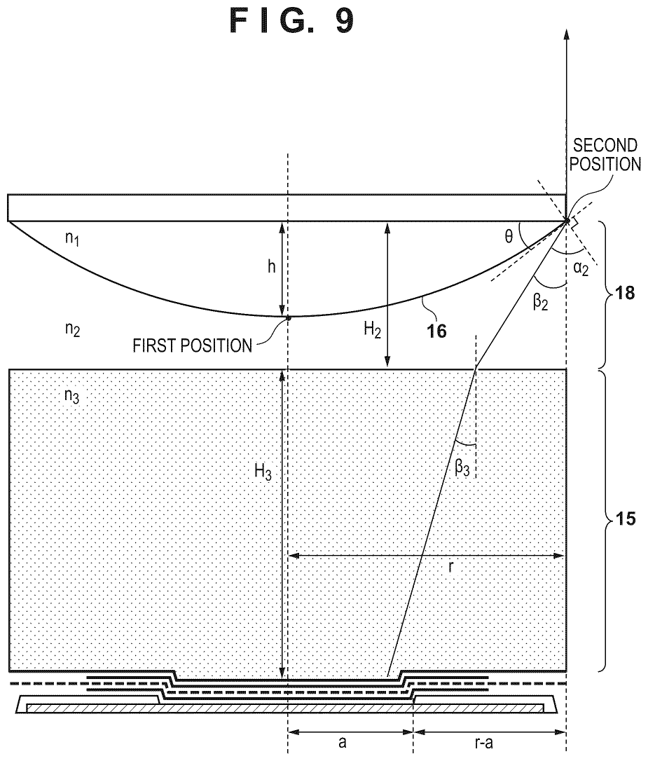

The second embodiment of the present disclosure will be described below. Matters not mentioned as the second embodiment can comply with the first embodiment. FIG. 8 is a schematic view exemplifying the sectional structure of a light emitting device 100 according to the second embodiment. FIG. 9 is an enlarged schematic view of a portion associated with a first light emitting portion SP1 and a microlens corresponding to it in FIG. 8. FIGS. 8 and 9 schematically show a section obtained by cutting the light emitting device 100 by a plane parallel to a normal to the surface of a substrate 1 and passing through the vertex of a curved portion of a microlens 16.

Portions different from the first embodiment will mainly be described below. In the second embodiment, the microlenses 16 are formed on a second substrate 17, and arranged to face the light emitting portion SP1 and light emitting portions SP2, . . . . The second substrate 17 need only be transparent, and the constituent material of the second substrate 17 may be the same as that of the above-described substrate 1. Since the microlenses 16 are formed on the second substrate 17, a restriction on the forming process of the microlenses is small and it is thus relatively easy to form the microlenses. In the second embodiment, a low refractive index layer 18 having a refractive index n₂ is arranged immediately below the microlenses 16 having a refractive index n₁. The low refractive index layer 18 is a layer having the refractive index n₂ smaller than the refractive index n₁ of the microlenses 16, and may be air or a gas such as nitrogen, or a transparent resin. In the second embodiment, the curved portion of the microlens 16 is a part of a spherical surface, and is a curved portion that is convex in a direction to approach the surface of the substrate 1 (that is, convex downward). As shown in FIG. 9, positive power acts on light from a light emitting portion by refraction on the interface between the low refractive index layer 18 and the curved portion of the microlens 16. Thus, similar to the first embodiment, the power consumption and driving lifetime are improved, and degradation in display quality caused by the screen-door effect is suppressed.

A preferable configuration according to the second embodiment will be described below. In the example shown in FIGS. 8 and 9, as described above, the curved portion of the microlens 16 is a part of a spherical surface, and a position (second position) at which a tilt angle θ of the curved portion of the microlens is maximum is the end of the curved portion of the microlens 16. When h represents a distance (microlens height) in the vertical direction from the vertex (first position) of the curved portion to the end of the curved portion and r represents a distance in the horizontal direction from the vertex of the curved portion to the end of the curved portion, θ is given by sin θ=2rh/(r²+h²) using h and r.

Consider a light beam that is extracted in air when light generated by the light emitting portion is refracted at the end (second position) of the curved portion of the microlens 16, that is, the position of the tilt angle θ. The light beam extracted in the front direction in air enters the curved portion of the microlens 16 at an incident angle α₂ (an angle with respect to the normal to the curved portion). Based on Snell's law, n₂·sin α₂=n₁·sin θ holds. A light beam angle β₂ of the light beam in the low refractive index layer 18 is given by α₂−θ.

Similar to the first embodiment, consider a condition that there exists a light beam passing through the end (second position) of the curved portion of the microlens 16 from the opening of the light emitting portion and extracted in the front direction. When H₂ represents the thickness of the low refractive index layer 18 at the second position and H₃ represents the thickness of a protection layer 15 in the vertical direction, expression (9) below is preferably satisfied.

$$r - a < {H}_{2} \cdot tan {β}_{2} + {H}_{3} \cdot tan {β}_{3} < r + a \qquad ( 9 )$$

In expression (9), a light beam angle β₃ in the protection layer 15 is an angle satisfying the following equation.

$${n}_{3} \cdot sin {β}_{3} = {n}_{2} \cdot sin {β}_{2}$$

That is, when expression (9) is satisfied, light emitted from the light emitting portion is refracted at the end (second position) of the curved portion of the microlens and extracted in the front direction, and the apparent light emission area is enlarged to πr². The enlargement effect of the apparent light emission area becomes larger than in a case where expression (9) is not satisfied. Thus, the effect of improving the power consumption and driving lifetime and the effect of suppressing degradation in display quality become large.

Furthermore, when nₑₘₗ represents the refractive index of an organic film 13, it is possible to improve the amount of light extracted in the front direction by setting an optical distance between a first reflective surface and a second reflective surface so as to satisfy equations (5) and (6) and expressions (7) and (8) with respect to θeml that satisfies a relationship of 0<θeml<sin⁻¹(n₂·sin β₂/nₑₘₗ).

In the above description, it has been considered a case where the curved portion of the microlens 16 is a part of a spherical surface and a point at which the tilt angle θ is largest is the end of the curved portion. However, the curved portion may be an aspherical surface, the second position at which the tilt angle θ is largest may not be the end of the curved portion, and the microlens layer may have a thickness at the second position.

An example in a case where the protection layer 15 is arranged between the light emitting portion and the low refractive index layer 18 has been explained. However, the constituent materials of the low refractive index layer 18 and the protection layer 15 may be the same and one layer may function as these layers. For example, between the light emitting portion and the low refractive index layer 18, other functional layers such as a color filter layer and/or a planarizing layer may be arranged or a plurality of layers may be arranged. If a plurality of layers having different refractive indices are arranged, the refractive index of the thickest layer may be n₃ or the average value of the refractive indices weighted in accordance with the thicknesses of the layers may be used. Furthermore, by calculating the light beam angle in consideration of refraction on the interface between the layers, the condition that the light beam refracted at the second position and extracted in the front direction exits from the light emitting portion may be considered. More specifically, in a case where n layers including the microlens layer are arranged, if the microlens layer is set as the first layer and the refractive index of the ith layer from the microlens layer in the stacking order is nᵢ, the light beam angle in the ith layer is given by the following equation, similar to the above-described example.

$${n}_{i} \cdot sin {β}_{i} = {n}_{2} \cdot sin {β}_{2}$$

Thus, when Hᵢ represents the thickness of the ith layer, the condition that the light beam refracted at the second position and extracted in the front direction exits from the opening of the light emitting portion is that a value obtained by adding Hᵢ·tan βᵢ up to the nth layer is larger than r−a and smaller than r+a. That is, expression (10) below is preferably satisfied.

$$r - a < {H}_{2} \cdot tan {β}_{2} + {H}_{3} \cdot tan {β}_{3} + … + {H}_{n} \cdot tan {β}_{n} < r + a \qquad ( 10 )$$

The preferable value range of the tilt angle θ at the second position of the microlens 16 according to this embodiment will be described next. As described above, the angle α₂ and the tilt angle θ of the microlens satisfy the relationship of n₂·sin α₂=n₁·sin θ. That is, when n₁·sin θ/n₂ is equal to or larger than 1, there is no light refracted at the second position of the microlens and extracted in the front direction. Therefore, by making n₁·sin θ/n₂ smaller than 1, the effect of improving the power consumption and driving lifetime and the effect of suppressing degradation in display quality become large. Furthermore, when the lens aberration is larger as n₁·sin θ/n₂ is closer to 1, a light beam that cannot effectively be used may be generated, thereby degrading the light extraction efficiency. The change of the light beam angle when the lens shape changes may be large and robustness to the lens shape may become low. Therefore, n₁·sin θ/n₂ is preferably small, and n₁·sin θ/n₂<0.98 is preferably satisfied and n₁·sin θ/n₂<0.95 is more preferably satisfied.

A practical example of a method of manufacturing the light emitting device 100 according to the second embodiment will be described below with reference to FIG. 8. Layers from first electrodes 2 to the protection layer 15 were formed on the substrate 1 by the same method as in the practical example of the first embodiment. Next, the microlenses 16 with a refractive index of 1.53 were formed on the second substrate 17 using an exposure process and a developing process. The curved portion of the microlens 16 was a part of a spherical surface, and the distance h in the vertical direction from the vertex (first position) of the curved portion to the end (second position) of the curved portion was 0.65 μm and the distance r in the horizontal direction was 1.9 μm. Next, the substrate 1 and the second substrate 17 were bonded so that the center of the opening OP of the first electrode and the center of the microlens 16 overlapped each other in a planar view. At this time, the substrate 1 and the second substrate 17 adhered to each other outside a display region, and the low refractive index layer between the protection layer 15 and the microlenses was air having a refractive index of 1. The distance in the vertical direction between the protection layer 15 and the second substrate 17 was 1 μm. That is, the distance in the vertical direction from the protection layer 15 to the second position of the microlens was 1 μm.

In the thus manufactured light emitting device 100, the curved portion, that is convex downward, of the microlens 16 formed on the second substrate 17 functioned to cause positive power to act on light from the light emitting portion. Thus, the power consumption was reduced, the driving lifetime was improved, and degradation in display quality caused by the screen-door effect was suppressed.

The tilt angle θ at the second position was calculated by sin θ=2rh/(r²+h²), thereby obtaining θ=37.8°. The incident angle α₂ on the lens surface and the light beam angle β₂ in the low refractive index layer 18 were calculated by n₂· sin α₂=n₁·sin θ and β₂=α₂−θ, thereby obtaining α=69.6° and β₂=31.8°, respectively. The light beam angle β₃ in the protection layer 15 was calculated by n₃·sin β₃=n₂·sin β₂, thereby obtaining β₃=15.5°. Since the distance H₂ in the vertical direction from the protection layer 15 to the second position of the microlens 16 was 1 μm and the thickness H₃ of the protection layer 15 was 2.1 μm, H₂·tan β₂+H₃·tan β₃=1.2 μm was obtained. On the other hand, since r−a=1 μm and r+a=2.8 μm, the relationship of expression (9) was satisfied. Furthermore, the radius a of the opening was 0.9 μm and r was 1.9 μm, thereby obtaining r/a=2.11. When the relationship of expression (9) was satisfied, the apparent opening was enlarged to a circle roughly having the radius r=1.9 μm. Thus, the effect of reducing the power consumption and improving the driving lifetime was large and the effect of suppressing degradation in display quality caused by the screen-door effect was large.

As the third embodiment, various kinds of devices incorporating the light emitting device 100 according to each of the first and second embodiments will exemplarily be described below. Note that the light emitting device 100 is suitable for an application in which the viewing angle is limited. Examples of the application include an application in which peep prevention is desired (for example, a portable apparatus such as a smartphone), a personal viewing display, a display for the passenger seat of a car, smartglasses, and an electronic viewfinder.

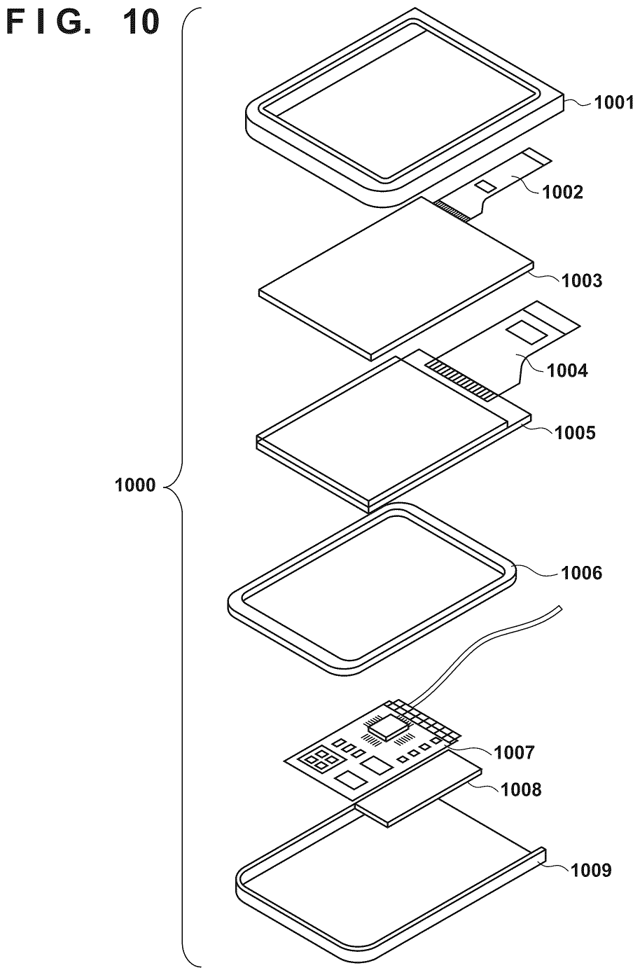

FIG. 10 is a schematic view showing a display device 1000 as an example of a display device according to this embodiment. The display device 1000 can include a touch panel 1003, a display panel 1005, a frame 1006, a circuit board 1007, and a battery 1008 between an upper cover 1001 and a lower cover 1009. The display panel 1005 is a display unit including the light emitting device 100 according to each of the first and second embodiments, and performs display using light emitted from the light emitting device 100. Flexible printed circuits (FPCs) 1002 and 1004 are respectively connected to the touch panel 1003 and the display panel 1005. A control circuit including transistors is printed on the circuit board 1007, thereby performing various control operations such as control of the display panel 1005. The battery 1008 is unnecessary if the display device is not a portable apparatus. Even when the display device is a portable apparatus, the battery 1008 may be provided at another position. The display device 1000 may include three kinds of color filters respectively corresponding to red, green, and blue. A plurality of color filters may be arranged using a delta arrangement.

The display device 1000 may be used as a display unit of a portable terminal. At this time, the display device 1000 can have both a display function and an operation function. Examples of the portable terminal are a portable phone such as a smartphone, a tablet, and a head mounted display.

The display device 1000 can be used for a display unit of an image capturing device including an optical unit having a plurality of lenses, and an image sensor for receiving light having passed through the optical unit. The image capturing device can include a display unit for displaying information (an image captured by the image sensor and the like) acquired by the image sensor. In addition, the display unit can be either a display unit exposed outside the image capturing device, or a display unit arranged in the finder. The image capturing device can be a digital camera or a digital video camera.

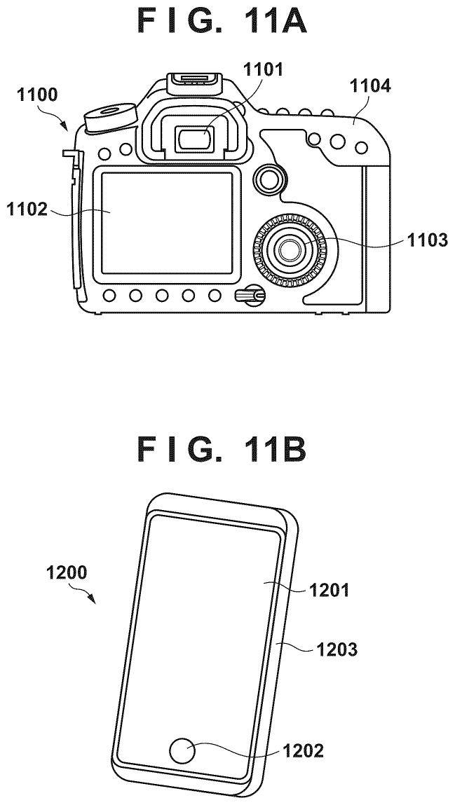

FIG. 11A is a schematic view showing an image capturing device 1100 as an example of an image capturing device according to this embodiment. The image capturing device 1100 can include an electronic viewfinder 1101, a rear display 1102, an operation unit 1103, and a housing 1104. The electronic viewfinder 1101 includes the display device including the light emitting device 100 according to each of the first and second embodiments, and performs display using light emitted from the light emitting device 100. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display device using the organic light emitting element having a high response speed. The display device using the organic light emitting element can be used for the devices that require a high display speed more preferably than for the liquid crystal display device.

The image capturing device 1100 includes an optical unit (not shown). This optical unit has a plurality of lenses, and forms an image of light on an image sensor accommodated in the housing 1104. The focal points of the plurality of lenses can be adjusted by adjusting the relative positions. This operation can also automatically be performed. The image capturing device 1100 may be called a photoelectric conversion device. The photoelectric conversion device can include, as an image capturing method, not a method of sequentially capturing images but a method of detecting the difference from a preceding image, a method of extracting a part of a recorded image, and the like.

FIG. 11B is a schematic view showing an electronic apparatus 1200 as an example of the electronic apparatus according to this embodiment. The electronic apparatus 1200 includes a display unit 1201, an operation unit 1202, and a housing 1203. The display unit 1201 includes a display device including the light emitting device 100 according to each of the first and second embodiments, and performs display using light emitted from the light emitting device 100. In the electronic apparatus 1200, the housing 1203 can accommodate a circuit, a printed board having this circuit, a battery, and a communication unit for performing external communication. The operation unit 1202 can be a button or a touch-panel-type reaction unit. The operation unit can also be a biometric authentication unit that performs unlocking or the like by authenticating the fingerprint. The electronic apparatus including the communication unit can also be regarded as a communication apparatus. The electronic apparatus may also have a camera function by including a lens and an image sensor. An image captured by the camera function is displayed on the display unit. Examples of the electronic apparatus are a smartphone and a notebook personal computer.

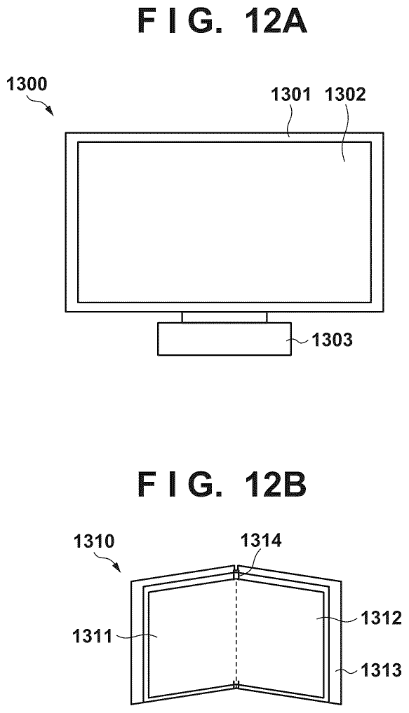

FIG. 12A is a schematic view showing a display device 1300 as an example of the display device according to this embodiment. The display device 1300 is a display device such as a television monitor or a PC monitor. The display device 1300 includes a frame 1301, a display unit 1302, and a base 1303 that supports the frame 1301 and the display unit 1302. The display unit 1302 includes a display device including the light emitting device 100 according to each of the first and second embodiments, and performs display using light emitted from the light emitting device 100. The form of the base 1303 is not limited to the form shown in FIG. 12A. The lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 12B is a schematic view showing a display device 1310 as another example of the display device according to this embodiment. The display device 1310 can be folded, and is a so-called foldable display device. The display device 1310 includes a first display unit 1311, a second display unit 1312, a housing 1313, and a bending point 1314. Each of the first display unit 1311 and the second display unit 1312 includes a display device including the light emitting device 100 according to each of the first and second embodiments, and performs display using light emitted from the light emitting device 100. The first display unit 1311 and the second display unit 1312 can also be one seamless display device. The first display unit 1311 and the second display unit 1312 can be divided by the bending point. The first display unit 1311 and the second display unit 1312 can display different images, and the first display unit 1311 and the second display unit 1312 can also display one image together.

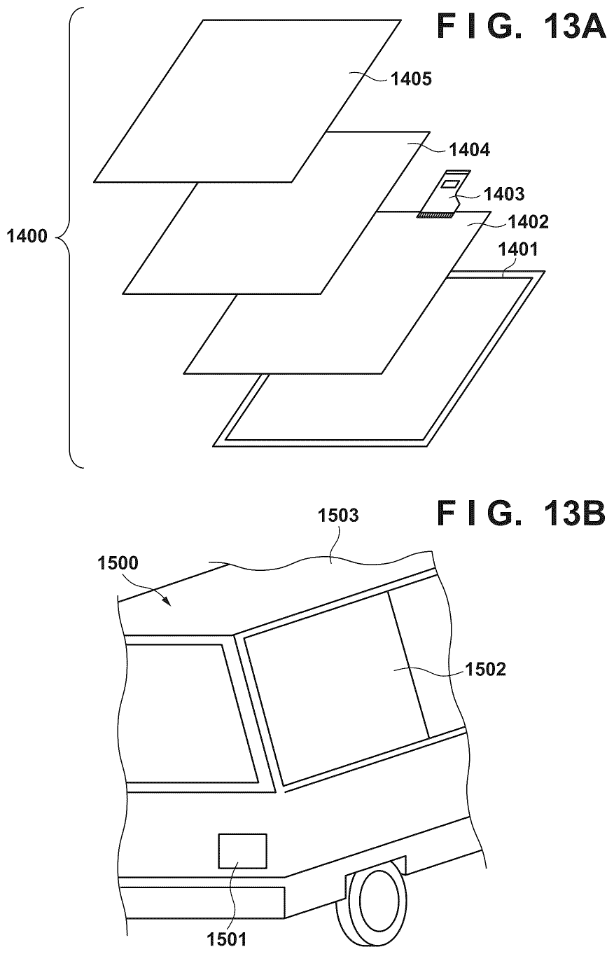

FIG. 13A is a schematic view showing an illumination device 1400 as an example of an illumination device according to this embodiment. The illumination device 1400 can include a housing 1401, a light source 1402, a circuit board 1403, an optical film 1404, and a light diffusing unit 1405. The light source 1402 includes the light emitting device 100 according to each of the first and second embodiments. The optical film 1404 can be a filter (optical filter) that improves the color rendering of the light source 1402. When performing lighting-up or the like, the light diffusing unit 1405 can throw the light of the light source 1402 over a broad range by effectively diffusing the light. The optical film 1404 and the light diffusing unit 1405 may be provided on the light emission side of the illumination device 1400. A cover may be provided on the outermost portion, as needed.

The illumination device 1400 is, for example, a device for illuminating the interior of the room. The illumination device 1400 can emit white light, natural white light, or light of another color (any color from blue to red). White has a color temperature of 4,200 K, and natural white has a color temperature of 5,000 K. The illumination device 1400 can also include a light control circuit for controlling the light emission colors of the illumination device 1400. The illumination device 1400 can also include a power supply circuit connected to the light source 1402. The power supply circuit is a circuit for converting an AC voltage into a DC voltage. The illumination device 1400 may include a color filter. In addition, the illumination device 1400 can include a heat radiation unit. The heat radiation unit radiates the internal heat of the device to the outside of the device, and examples are a metal having a high specific heat and liquid silicon.

FIG. 13B is a schematic view showing an automobile 1500 that is an example of a moving body according to this embodiment. The automobile 1500 can include a taillight 1501 that is an example of a lighting appliance. The taillight 1501 is turned on when performing a braking operation or the like.

The taillight 1501 includes the light emitting device 100 according to each of the first and second embodiments. The taillight 1501 can include a protection member for protecting the light emitting device. The material of the protection member is not limited as long as the material is a transparent material with a strength that is high to some extent, and the protection member is preferably made of polycarbonate or the like. A furandicarboxylic acid derivative, an acrylonitrile derivative, or the like may be mixed in polycarbonate.

The automobile 1500 can include a vehicle body 1503, and a window 1502 attached to the vehicle body 1503. The window 1502 can be a window for checking the front and back of the automobile 1500, and otherwise, can be a transparent display. The transparent display includes the display device including the light emitting device 100 according to each of the first and second embodiments, and performs display using light emitted from the light emitting device 100. In this case, the constituent materials of the electrodes and the like of the light emitting device are formed by transparent members.

The moving body according to this embodiment may be a ship, an aircraft, a drone, or the like. The moving body may include a main body and a lighting appliance provided in the main body. The lighting appliance may emit light to show the position of the main body. The lighting appliance includes the light emitting device 100 according to each of the first and second embodiments.

The display device according to this embodiment includes the display device including the light emitting device 100 according to each of the first and second embodiments, and can be applied to a wearable device such as smartglasses, an HMD, or a smart contact lens. The display device according to this embodiment can also be applied to a system including a wearable device. An image capturing display device used as a wearable device or the like includes an image capturing device capable of photoelectrically converting visible light and a display device capable of emitting visible light.

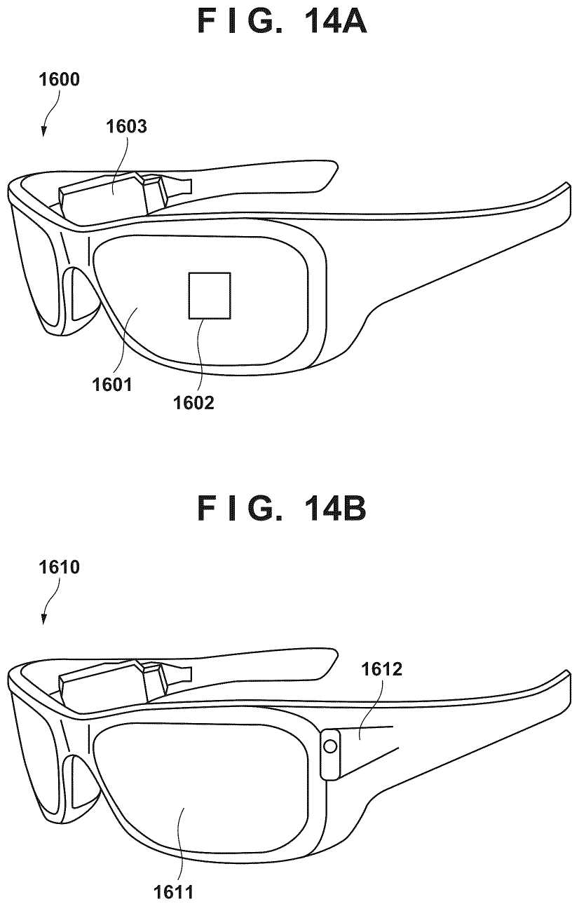

FIG. 14A is a schematic view showing glasses 1600 (smartglasses) as an example of the wearable device according to this embodiment. An image capturing device 1602 such as a CMOS sensor or a SPAD is provided on the surface side of a lens 1601 of the glasses 1600. In addition, the display device including the light emitting device 100 according to each of the first and second embodiments is provided on the back surface side of the lens 1601, thereby performing display using light emitted from the light emitting device 100.

The glasses 1600 further include a control device 1603. The control device 1603 functions as a power supply that supplies electric power to the image capturing device 1602 and the above-described display device. In addition, the control device 1603 controls the operations of the image capturing device 1602 and the display device. An optical system configured to condense light to the image capturing device 1602 is formed on the lens 1601.

FIG. 14B is a schematic view showing glasses 1610 (smartglasses) as an example of the wearable device according to this embodiment. The glasses 1610 include a control device 1612. An image capturing device corresponding to the image capturing device 1602 and the display device according to this embodiment are mounted on the control device 1612. The image capturing device in the control device 1612 and an optical system configured to project light emitted from the display device are formed in a lens 1611, and an image is projected to the lens 1611. The control device 1612 functions as a power supply that supplies electric power to the image capturing device and the display device, and controls the operations of the image capturing device and the display device.

The control device may include a line-of-sight detection unit that detects the line of sight of a wearer of the glasses 1610. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of the quality of the image projected on the lens 1611 from the display device. The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used. More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

When performing display control based on line-of-sight detection, the light emitting device 100 according to each of the first and second embodiments can suitably be applied to smartglasses including an image capturing device configured to capture the outside. The smartglasses can display captured outside information in real time.

The above-described display device can include an image capturing device including a light receiving element, and control a displayed image based on the line-of-sight information of the user from the image capturing device. More specifically, the display device decides a first visual field region at which the user is gazing and a second visual field region other than the first visual field region based on the line-of-sight information. The first visual field region and the second visual field region may be decided by the control device of the display device, or those decided by an external control device may be received by the display device. In the display region of the display device, the display resolution of the first visual field region may be controlled to be higher than the display resolution of the second visual field region. That is, the resolution of the second visual field region may be lower than that of the second visual field region.

In addition, the display region can include a first display region and a second display region different from the first display region, and a region of higher priority can be decided from the first display region and the second display region based on line-of-sight information. The first display region and the second display region may be decided by the control device of the display device, or those decided by an external control device may be received by the display device. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

As described above, when the light emitting device according to each of the first and second embodiments is used for various kinds of devices, it is possible to perform display with high quality and good light emission.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting device comprising a plurality of light emitting portions on a surface of a substrate, wherein
each of the plurality of light emitting portions includes, on the surface, a first electrode, a first light emitting layer, a charge generation layer, a second light emitting layer configured to generate light of the same color as a color of light generated by the first light emitting layer, and a second electrode in this order,
the plurality of light emitting portions include a light emitting portion configured to generate light of a first wavelength and a light emitting portion configured to generate light of a second wavelength different from the first wavelength, and
a lens having positive power is provided on each of the plurality of light emitting portions.

2. The light emitting device according to claim 1, wherein
a light beam emitted from a given point in a light emission region of the light emitting portion is refracted, in a direction parallel to a normal to the surface, at a position in a curved portion of the lens where a tilt angle with respect to a plane parallel to the surface is largest.

3. The light emitting device according to claim 1, wherein
the lens includes a curved portion that is convex in a direction away from the surface,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
h represents a distance from the first position to the second position in the first direction,
r represents a distance from the first position to the second position in a second direction parallel to the surface,
H₁ represents a distance from the light emitting portion to the second position in the first direction,
a represents a distance from a center of the light emitting portion to an end of the light emitting portion in the second direction, and
n₁ represents a refractive index of the lens, no represents a refractive index of a medium contacting the curved portion of the lens on a light extraction side, and θ represents a tilt angle of the curved portion at the second position,
an angle β₁ given by n₁·sin α=n₀·sin θ and β₁=θ−α satisfies a relationship of r−a<H₁·tan β₁<r+a.

4. The light emitting device according to claim 1, wherein
a layer having a refractive index n₂ is arranged between the light emitting portion and the lens,
the lens includes a curved portion that is convex in a direction away from the surface,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
h represents a distance from the first position to the second position in the first direction,
r represents a distance from the first position to the second position in a second direction parallel to the surface,
H₁ represents a thickness of the lens at the second position in the first direction,
a represents a distance from a center of the light emitting portion to an end of the light emitting portion in the second direction,
H₂ represents a thickness of the layer in the first direction, and
n₁ represents a refractive index of the lens, no represents a refractive index of a medium contacting the curved portion of the lens on a light extraction side, and θ represents a tilt angle of the curved portion at the second position,
angles β₁ and β₂ given by n₁·sin α=n₀·sin θ, β₁=θ−α, and n₂·sin β₂=n₁·sin β₁ satisfy a relationship of r−a<H₁·tan β₁+H₂·tan β₂<r+a.

5. The light emitting device according to claim 1, wherein
a first layer having a refractive index n₃ is arranged between the light emitting portion and the lens,
a second layer having a refractive index n₂ is arranged between the lens and the first layer in contact with the lens,
the lens includes a curved portion that is convex in a direction to approach the surface,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
h represents a distance from the first position to the second position in the first direction,
r represents a distance from the first position to the second position in a second direction parallel to the surface,
H₁ represents a thickness of the lens at the second position in the first direction,
a represents a distance from a center of the light emitting portion to an end of the light emitting portion in the second direction,
H₃ represents a thickness of the first layer in the first direction,
H₂ represents a thickness of the second layer in the first direction, and
n₁ represents a refractive index of the lens, and θ represents a tilt angle of the curved portion at the second position,
angles β₂ and β₃ given by n₂·sin α₂=n₁·sin θ, β₂=α₂−θ, and n₃·sin β₃=n₂·sin β₂ satisfy a relationship of r−a<H₂·tan β₂+H₃·tan β₃<r+a.

6. The light emitting device according to claim 1, wherein
a first layer having a refractive index n₃ is arranged between the light emitting portion and the lens,
a second layer having a refractive index n₂ is arranged between the lens and the first layer in contact with the lens,
the lens includes a curved portion that is convex in a direction to approach the surface,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
n₁ represents a refractive index of the lens, and θ represents a tilt angle of the curved portion at the second position,
a relationship of n₁·sin θ/n₂>1 is satisfied.

7. The light emitting device according to claim 1, wherein
a vertex of a curved portion of the lens in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
r represents a distance from the first position to the second position in a second direction parallel to the surface, and
a represents a distance from a center of the light emitting portion to an end of the light emitting portion in the second direction,
r/a>1 is satisfied.

8. The light emitting device according to claim 1, wherein
a vertex of a curved portion of the lens in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
r represents a distance from the first position to the second position in a second direction parallel to the surface, and
a represents a distance from a center of the light emitting portion to an end of the light emitting portion in the second direction,
a relationship of r/a<5 is satisfied.

9. The light emitting device according to claim 1, wherein
a vertex of a curved portion of the lens in a first direction parallel to a normal to the surface is set as a first position, and a position in the curved portion at which a tilt angle with respect to a plane parallel to the surface is largest in a section parallel to the normal and passing through the first position is set as a second position, and
in a case where in the section,
h represents a distance from the first position to the second position in the first direction, and
r represents a distance from the first position to the second position in a second direction parallel to the surface,
a relationship of h/r<0.95 is satisfied.

10. The light emitting device according to claim 1, wherein
the light emitting portion includes two reflective surfaces,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where n₁ represents a refractive index of the lens, n₀ represents a refractive index of a medium contacting the curved portion of the lens on a light extraction side, and θ represents a tilt angle of the curved portion at the second position,
(2×m−Φ/π)×(λ/4)×1/cos(θeml)−λ/8<L<(2×m−Φ/π)×(λ/4)×1/cos(θeml)+λ/8 is satisfied,
where L represents an optical path length between the two reflective surfaces, λ represents a peak wavelength of a PL spectrum of a light emitting material contained in the light emitting portion, m represents an integer not less than 0, Φ represents a sum of reflection phases on the two reflective surfaces at λ, and θeml represents an arbitrary angle that satisfies 0<sin θeml<n₁·sin β₁/nₑₘₗ using an angle β₁ given by n₁·sin α=n₀·sin θ and β₁=θ−α in a case where nₑₘₗ represents a refractive index of an organic film including the first light emitting layer and the second light emitting layer.

11. The light emitting device according to claim 1, wherein
the light emitting portion includes two reflective surfaces,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where n₁ represents a refractive index of the lens, n₀ represents a refractive index of a medium contacting the curved portion of the lens on a light extraction side, and θ represents a tilt angle of the curved portion at the second position,
(2mπ−Φ)×(λ/4π)<L<(2×m−Φ/π)×(λ/4)×1/cos(θeml)+λ/8 is satisfied,
where L represents an optical path length between the two reflective surfaces, λ represents a peak wavelength of a PL spectrum of a light emitting material contained in the light emitting portion, m represents an integer not less than 0, @ represents a sum of reflection phases on the two reflective surfaces at λ, and θeml represents an arbitrary angle that satisfies 0<sin θeml<n₁·sin β₁/nₑₘₗ using an angle β₁ given by n₁·sin α=n₀·sin θ and β₁=θ−α in a case where nₑₘₗ represents a refractive index of an organic film including the first light emitting layer and the second light emitting layer.

12. The light emitting device according to claim 1, wherein
a PL spectrum of a first light emitting material contained in the first light emitting layer has a first peak of a wavelength APL in a visible light region, and
a resonant peak wavelength λₒₙ of an interference spectrum that intensifies light emitted in a direction perpendicular to the surface, a peak wavelength λ_{EL} of light emitted from the light emitting portion, and the wavelength λ_{PL} satisfy a relationship of |λ_{EL}−λ_{PL}|<|λₒₙ−λ_{PL}|.

13. The light emitting device according to claim 1, wherein
a PL spectrum of a first light emitting material contained in the first light emitting layer has a first peak of a wavelength APL in a visible light region,
a vertex of the curved portion in a first direction parallel to a normal to the surface is set as a first position, and a position in the curved portion at which a tilt angle with respect to a plane parallel to the surface is largest in a section parallel to the normal and passing through the first position is set as a second position, and
in a case where n₁ represents a refractive index of the lens, no represents a refractive index of a medium contacting the curved portion of the lens on a light extraction side, and θ represents a tilt angle of the curved portion at the second position,
a resonant peak wavelength λₒₙ of an interference spectrum that intensifies light emitted in a direction perpendicular to the surface, a resonant peak wavelength λ_{off} of an interference spectrum that intensifies light exiting in a θeml direction satisfying 0<sin θeml<n₁·sin β₁/nₑₘₗ, and the wavelength λ_{PL} satisfy a relationship of |λ_{off}−λ_{PL}|<|λₒₙ−λ_{PL}|,
where an angle β₁ is given by n₁·sin α=n₀·sin θ and β₁=θ−α.

14. The light emitting device according to claim 1, wherein
no layer having a refractive index lower than a refractive index of the lens is included between the light emitting portion and the lens.

15. A display device comprising:
a display unit including a light emitting device defined in claim 1; and
a control circuit configured to control the display unit.

16. An image capturing device comprising:
an optical unit;
an image sensor configured to receive light having passed through the optical unit; and
a display unit configured to display an image captured by the image sensor,
wherein the display unit includes a light emitting device defined in claim 1.

17. An electronic apparatus comprising:
a display unit including a light emitting device defined in claim 1;
a housing provided with the display unit; and
a communication unit provided in the housing and configured to perform external communication.
